(19) United States
(12) Patent Application Publication
(10) Pub. No.: US 2014/0177192 A1
(43) Pub. Date: Jun. 26, 2014

(54) CORE SUBSTRATE AND METHOD FOR MANUFACTURING THE SAME, AND SUBSTRATE WITH BUILT-IN ELECTRONIC COMPONENTS AND METHOD FOR MANUFACTURING THE SAME

(71) Applicant: SAMSUNG ELECTRO-MECHANICS CO., LTD., Suwon (KR)

(72) Inventors: Seung Eun Lee, Sungnam (KR); Yee Na SHIN, Suwon (KR); Yul Kyo CHUNG, Yongin (KR); Doo Hwan LEE, Daejeon (KR)

(73) Assignee: SAMSUNG ELECTRO-MECHANICS CO., LTD., Suwon (KR)

(21) Appl. No.: 14/104,482

(22) Filed: Dec. 12, 2013

(30) Foreign Application Priority Data
Dec. 26, 2012 (KR) 10-2012-0153375

(51) Int. Cl. H05K 1/18; H05K 3/44; H05K 3/30

(52) U.S. Cl. CPC H05K 1/185; H05K 3/30; H05K 3/44
USPC 361/761; 428/212; 29/832

(57) ABSTRACT

The present invention relates to a core substrate, a manufacturing method thereof, and a substrate with built-in electronic components and a method for manufacturing the same. In accordance with an embodiment of the present invention, a core substrate including: a first insulating layer; and a second insulating layer stacked on upper and lower surfaces of the first insulating layer and made of a material with a glass transition temperature lower than that of the first insulating layer.

### CROSS-REFERENCE TO RELATED APPLICATIONS

Claim and incorporate by reference domestic priority application and foreign priority application as follows:

### “CROSS REFERENCE TO RELATED APPLICATION

This application claims the foreign priority benefit under 35 U.S.C. Section 119 of Korean Application No. 10-2012-0153375, filed Dec. 26, 2012, which is hereby incorporated by reference in its entirety into this application.”

### BACKGROUND OF THE INVENTION

1. Field of the Invention

The present invention relates to a core substrate, a manufacturing method thereof, and a substrate with built-in electronic components and a method for manufacturing the same.

2. Description of the Related Art

In order to minimize the warpage during the manufacturing a conventional package substrate, a core material with a low CTE (Coefficient of Thermal Expansion) and a build-up material have been used. In case of the embedded substrate, a cavity is fabricated on the core substrate; an electronic component is incorporated therein. At this time, if the overall thickness of the substrate is uniform, since the warpage of the whole substrate becomes to be reduced as the thickness of the core with a lower CTE becomes thicker, the thick core is used. Accordingly, the volume of the cavity gap of the core incorporated therein the electronic component increases; it is possible to generate a void failure not to sufficiently fill the cavity gap in the build-up material. And also, in order to reduce the warpage, the build-up material adopts a material with a low CTE, since the amount of resin is relatively small in case of the material with the low CTE; the danger to generate failure not to fill the cavity gap becomes larger.

### RELATED ART DOCUMENT

### Patent Document

Patent Document 1: U.S. Patent Laid-open Publication No. US 2011/0225816 (laid-open on Sep. 22, 2011)

### SUMMARY OF THE INVENTION

It is, therefore, an object of the present invention to provide a core substrate to be utilized for manufacturing a substrate with built-in electronic components and a substrate with built-in electronic components improved in mechanical characteristics and reliability.

Another object of the present invention is to provide methods for manufacturing the core substrate and the substrate with built-in electronic components improved in mechanical characteristics and reliability.

In order to overcome the above-described problems, in accordance with a first embodiment of the present invention, there is provided a core substrate including: a first insulating layer; and a second insulating layer stacked on upper and lower surfaces of the first insulating layer and made of a material with a glass transition temperature lower than that of the first insulating layer.

At this time, in an example, the core substrate further includes a metal layer stacked on upper and lower surfaces of the second insulating layer.

And also, in another example, the first insulating layer includes a thermoplastic resin.

And, in an example, the first insulating layer is a semi-hardening insulating layer and the second insulating layer is a hardening insulating layer.

Thereafter, in order to overcome the above-described problems, in accordance with the second embodiment of the present invention, there is provided a substrate with built-in electronic components including: a core substrate provided with a cavity and including a first insulating layer and a second insulating layer stacked on upper and lower surfaces of the first insulating layer, wherein the second insulating layer is made of a material with a glass transition temperature lower than that of the first insulating layer; and electronic component fixed by an insulating material flown from the first insulating layer by being inserted into the cavity.

At this time, in an example, the substrate with built-in electronic components further including a circuit pattern layer formed on upper and lower surfaces of the second insulating layer of the core substrate.

And also, in an example, the first insulating layer includes a thermoplastic resin.

And also, in an example, the substrate with built-in electronic components further includes a third insulating layer for covering the circuit pattern layer by being stacked on the second insulating layer.

At this time, a gap is formed between a sidewall of the cavity and the electronic component and the gap is filled with the third insulating layer together with the first insulating layer.

In addition, in order to overcome the above-described problems, in accordance with the third embodiment, there is provided a method for manufacturing a substrate with built-in electronic components including: preparing a core substrate provided with a cavity and including a first insulating layer and a second insulating layer stacked on upper and lower surfaces of the first insulating layer, wherein the second insulating layer is made of a material with a glass transition temperature lower than that of the first insulating layer; inserting the electronic component into the cavity; and fixing the electronic component by flowing an insulating material of the first insulating layer into a gap between the cavity and the electronic component by thermal compressing the core substrate inserted therein the electronic component.

At this time, in an example, the core substrate further includes a metal layer formed on the second insulating layer, and further includes forming a circuit pattern by fabricating the metal layer.

And also, at this time, the method for manufacturing a substrate with built-in electronic components further includes forming a third insulating layer to cover the second insulating layer and the circuit pattern.

At this time, the gap is filled with the third insulating layer together with the first insulating layer.

And also, in an example, preparing the core substrate includes: stacking the second insulating layer on the upper and the lower surfaces of the first insulating layer; and compressing the second insulating layer and the first insulating layer under a temperature lower than the glass transition temperature of the first insulating layer and higher than the glass transition temperature of the second insulating layer.

And also, in an example, thermal compressing the core substrate is performed at a temperature higher than the glass transition temperature of the first insulating layer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a core substrate in accordance with an embodiment of the present invention;

FIGS. 2A and 2B are views schematically showing a core substrate in accordance with another embodiment of the present invention;

FIGS. 3A to 3D are views schematically showing each step of a method for manufacturing a core substrate in accordance with another embodiment of the present invention;

FIGS. 4A and 4B are views schematically showing a substrate with built-in electronic components in accordance with another embodiment of the present invention; and

FIGS. 5A to 5E are views schematically showing each step of a method for a substrate with built-in electronic components in accordance with still another embodiment of the present invention.

### DETAILED DESCRIPTION OF THE PREFERABLE EMBODIMENTS

Embodiments of the present invention to achieve the above-described objects will be described with reference to the accompanying drawings. In this description, the same elements are represented by the same reference numerals, and additional description which is repeated or limits interpretation of the meaning of the invention may be omitted.

In this specification, when an element is referred to as being “connected or coupled to” or “disposed in” another element, it can be “directly” connected or coupled to or “directly” disposed in the other element or connected or coupled to or disposed in the other element with another element interposed therebetween, unless it is referred to as being “directly coupled or connected to” or “directly disposed in” the other element.

Although the singular form is used in this specification, it should be noted that the singular form can be used as the concept representing the plural form unless being contradictory to the concept of the invention or clearly interpreted otherwise. It should be understood that the terms such as “having”, “including”, and “comprising” used herein do not preclude existence or addition of one or more other elements or combination thereof.

The drawings referenced in this specification are provided as examples to describe the embodiments of the present invention, and the shape, the size, and the thickness may be exaggerated in the drawings for effective description of technical features.

### Core Substrate

First, a core substrate in accordance with a first embodiment of the present invention will be specifically described with reference to the drawings. At this time, the reference numeral that is not mentioned in the reference drawing may be the reference numeral that represents the same element in another drawing.

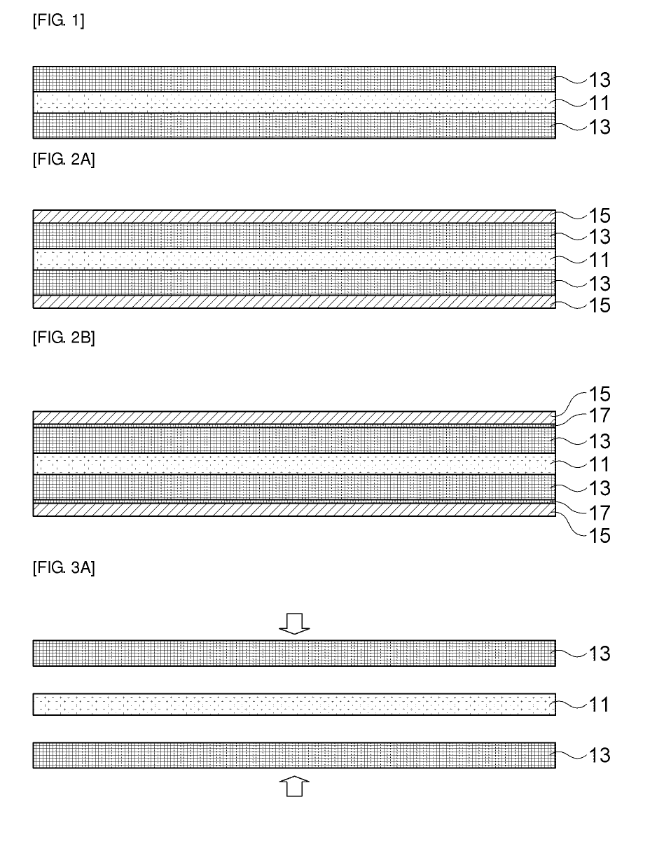

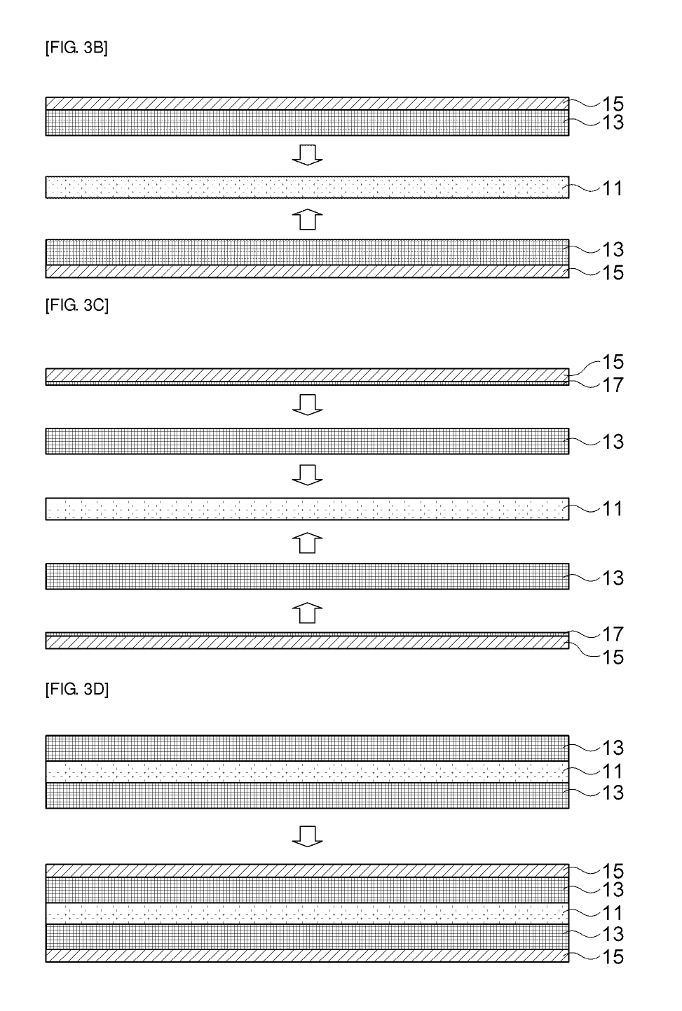

FIG. 1 is a view schematically showing a core substrate in accordance with an embodiment of the present invention; and FIGS. 2A and 2B are views schematically showing a core substrate in accordance with another embodiment of the present invention.

Referring to FIG. 1, a core substrate in accordance with an example includes a first insulating layer 11 and a second insulating layer 13. At this time, the second insulating layer 13 is attached to the upper and lower surfaces of the first insulating layer 11.

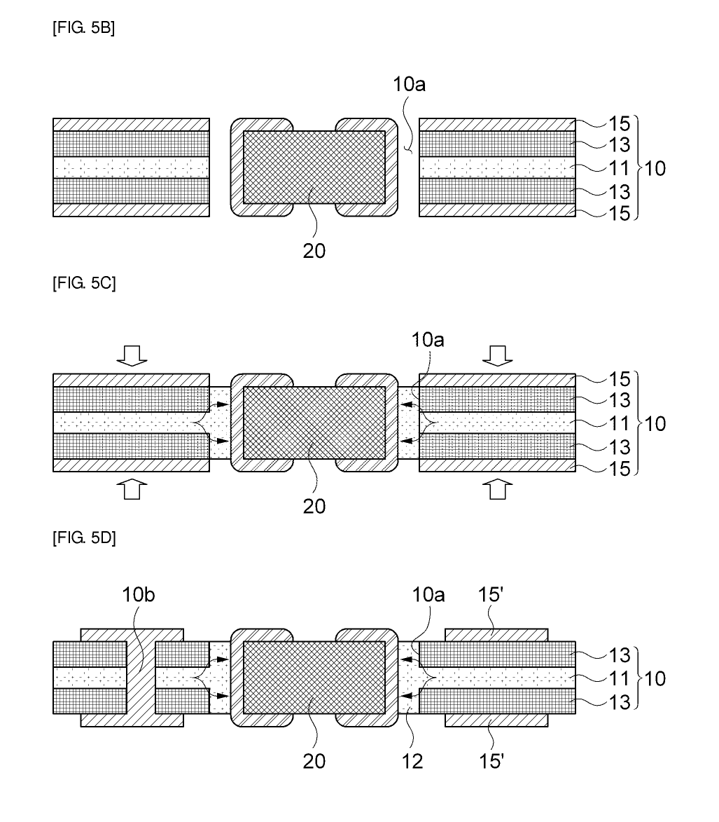

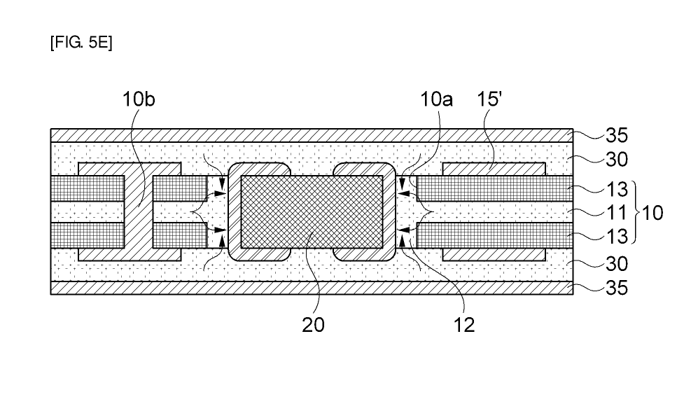

The first insulating layer 11 can include an insulating material with a glass transition temperature Tg higher than that of the second insulating layer 13. Since the glass transition temperature of the first insulation layer 11 to form an intermediate layer is higher than that of the second insulating layer, the second insulating layer 13 can be solidified when it is compressed at a constant temperature, for example, lower than the glass transition temperature of the first insulating layer 11 and higher than the glass transition temperature of the second insulating layer, during the core substrate manufacturing process. At this time, since the solidification of the second insulating layer 13 is finished, a resin flow is not generated in the cavities (referring to the reference numeral 10a in FIGS. 4A and 5A) when the substrate with built-in electronic components is manufactured later. Whereas, since the first insulating layer 11 as a layer inserted into a middle position remains uncured without proceeding the cure during the core substrate manufacturing, after the electronic component are inserted into the cavities (referring to the reference numeral 10a in FIGS. 4A and 5A) during the manufacturing the substrate with built-in electronic components later, in case when the second insulating layer 13 stacked on the upper and lower peripheral regions of the first insulating layer 11 are thermally compressed, the material of the first insulating layer 11 as an intermediate layer flows into a gap between the cavity 10a and the electronic component at a flow state to thereby fix the electronic component. Accordingly, the void formation can be suppressed at spaces between the cavities 10a and the built-in electronic components (referring to the reference numeral 20 in FIGS. 4A and 5B).

In one example, the first insulating layer 11 can include a thermoplastic resin. By forming the first insulating layer 11 as a material including the thermoplastic resin, for example, in case when the electronic component 20 is incorporated into the cavities 10a of the core substrate (referring to the reference numeral 10 of FIGS. 4A and 5A), the first insulating layer material flows into the spaces between the cavities 10a and the built-in electronic components at a flow state by the thermal compression, thereby fixing the electronic component (referring to the reference numeral 20 of FIGS. 4A and 5A).

And also, in an example, the first insulating layer 11 may be a semi-cured insulating layer. Since the first insulating layer 11 is a semi-cured state, for example, in case when the electronic component 20 is incorporated into the cavities 10a of the core substrate (referring to the reference numeral 10 of FIGS. 4A and 5A), if the second insulating layer 13 is compressed, the first insulating layer material as the intermediate layer flows into the spaces between the cavities 10a and the built-in electronic components at a flow state, thereby fixing the electronic component 20. At this time, the second insulating layer 13 of the core substrate 10 may be a cured insulating layer.

Thereafter, referring to FIG. 1, the second insulating layer 13 is stacked on the upper and lower regions of the first insulating layer 11. For example, the second insulating layer 13 may be a cured insulating layer. For example, during the manufacturing process of the core substrate, the semi-cured second insulating layer 13 is stacked on the upper and lower regions of the first insulating layer 11 and cured to thereby form the core substrate on which the cured second insulating layer 13 is stacked on the upper and lower regions of the first insulating layer. And also, the second insulating layer 13 may be a prepreg layer. And also, in one example, the second insulating layer 13 may be a thermosetting material or a thermoplastic material.

And also, referring to FIG. 2A and FIG. 2B, in one example, the core substrate 10 can further include a metal layer 15. At this time, the metal layer 15 is stacked on the upper and lower regions of the second insulating layer 13, that is, the upper region of the second insulating layer 13 stacked on the upper region of the first insulating layer 11, and the lower region of the second insulating layer 13 stacked on the lower region of the first insulating layer, respectively. For example, as shown in FIG. 2A, the metal layer 15 is directly attacked on the second insulating layer 13 or, as shown in FIG. 2B, the metal layer 15 may be attached on the second insulating layer 13 by the medium of an attaching resin or a primer resin 17. For, example, the metal layer 15 may be a copper foil, but it is not limited to this.

### Method for Manufacturing the Core Substrate

And then, a method for manufacturing a core substrate in accordance with a second embodiment of the present invention will be specifically described with reference to the drawings. At this time, the core substrate in accordance with the above-described first embodiment and FIGS. 1A to 2B will be referred; and, accordingly, the overlapped explanations will be omitted.

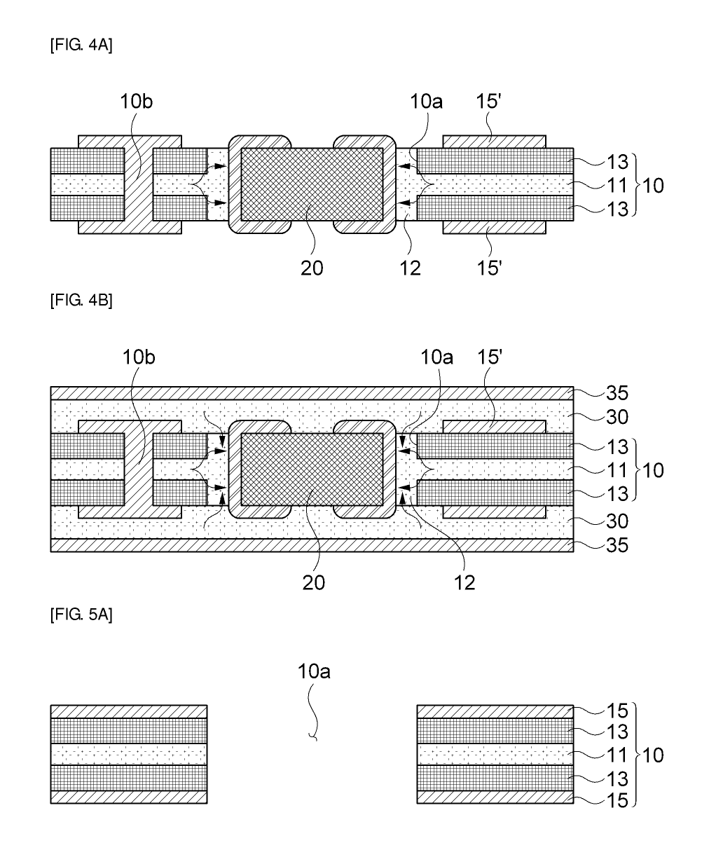

FIGS. 3A to 3D are views schematically showing each step of a method for manufacturing a core substrate in accordance with another embodiment of the present invention.

Referring to FIG. 3A, the method for manufacturing the core substrate in accordance with one example forms a core substrate 10 by stacking a second insulating layer 13 having a glass transition temperature lower than that of a first insulating layer 11 on upper and lower regions of the first insulating layer 11. That is, the method for manufacturing the core substrate includes the steps of: preparing the first insulating layer; and stacking the second insulating layer.

At first, in the step of preparing the first insulating layer, the first insulating layer 11 is prepared. At this time, the material of the first insulating layer 11 has a glass transition temperature higher than that of the second insulating layer 13 to be stacked on the upper and lower regions of the first insulating layer 11. Accordingly, during the manufacturing of the core substrate 10, by stacking the second insulating layer 13 of the material with the glass transition temperature lower than that of the first insulating layer 11 on the upper and lower regions of the first insulating layer 11, if it is cured by thermally compressing at a predetermined temperature, for example, a temperature lower than the glass transition temperature of the first insulating layer 11 and higher than the glass transition temperature of the second insulating layer 13, the second insulating layer 13 with a lower glass transition temperature is cured and the first insulating layer 11 as an intermediate layer remains uncured. Accordingly, during the manufacturing a substrate with built-in electronic components in the future, the electronic component (referring to the reference numeral 20 of FIGS. 4A and 5B) are inserted into the cavities (referring to the reference numeral 10a of FIGS. 4A and 5A) formed on the core substrate (referring to the reference numeral 10 of FIGS. 4A and 5A), if the previously cured second insulating layer is thermally compressed, the first insulating layer 11 as the intermediate layer becomes a flow state and flows into spaces between the cavities 10a and the electronic component, thereby fixing the electronic component 20. That is, during the manufacturing the substrate with built-in electronic components, a resin flow occurs in the first insulating layer 11 as the intermediate insulating layer.

For example, the press temperature is higher than the glass transition temperature of the second insulating layer 13 during the manufacturing the core substrate and can be compressed at a temperature range lower than the glass transition temperature of the first insulating layer 11 as the intermediate insulating layer. On the other hands, in case of manufacturing the substrate with built-in electronic components, in order to fix the electronic component (referring to the reference numeral 20 of FIGS. 4A and 5B), by compressing at a temperature higher than the glass transition temperature of the first insulating layer 11 as the intermediate insulating layer, gaps of the cavities 10a may be filled by allowing the first insulating layer 11 as the intermediate insulating layer to be a flow state. At this time, in case when the first insulating layer 11 of the core substrate is a semi-cured state previously, in case of manufacturing the substrate with built-in electronic components, although it is compressed at a temperature lower than the glass transition temperature of the first insulating layer 11, the first insulating layer 11 may be flow into the gaps of the cavities 10a.

In one example, the first insulating layer 11 may include a thermoplastic resin. Since the first insulating layer 11 is the thermoplastic resin, for example, during the manufacturing of the substrate with built-in electronic components, the electronic component 20 is inserted into the cavities 10a formed in the core substrate 10, if the second insulating layer 13 of the core substrate 10 is thermally compressed, the first insulating layer 11 as the thermoplastic resin easily flows into the spaces between the cavities 10a and the electronic component at a flow state, thereby fixing the electronic component 20.

And also, in one example, the first insulating layer 11 may be a semi-cured insulating layer. The first insulating layer 11 and the second insulating layer 13 are stacked at the semi-cured state, and then, it is cured at a predetermined temperature, for example, a temperature lower than the glass transition temperature of the first insulating layer 11, in order to manufacture the core substrate, the second insulating layer 13 having a low glass transition temperature is cured and the first insulating layer 11 remains at the semi-cured state continuously. At this time, in case when the electronic component 20 is incorporated into the cavities 10a of the formed core substrate 10, if the second insulating layer 13 is compressed, the material of the first insulating layer 11 as the intermediate layer of the semi-cured state flows into the spaces between the cavities 10a and the built-in electronic components at the flow state, thereby fixing the electronic component 20.

Thereafter, in the steps of stacking the second insulating layer, the second insulating layer 13 is stacked on the upper and lower regions of the first insulating layer 11. For example, at this time, the stacked second insulating layer 13 may be an insulating layer of the cured state, or may be an insulating layer of the semi-cured state. Although the second insulating layer 13 is the semi-cured state, for example, it may be attached to the upper and lower regions of the first insulating layer 11 of the semi-cured state with attaching a copper film to one side peripheral region. By stacking the second insulating layer 13 of the semi-cured state on the first insulating layer 11 of the semi-cured state, it is cured at a temperature lower than the glass transition temperature of the first insulating layer 11 in order to manufacture the core substrate, the second insulating layer 13 is cured and the first insulating layer 11 can manufacture the core substrate in the semi-cured state. And then, during the manufacturing the substrate with built-in electronic components, the electronic component 20 is inserted into the cavities 10a formed in the core substrate 10, in case of thermally compressing the core substrate 10, since the first insulating layer 11 remained at the semi-cured state becomes the flow state and flows into the spaces between the cavities 10a and the electronic component, the electronic component can be fixed by the first insulating layer 11.

And also, at this time, the second insulating layer 13, for example, may be a prepreg layer.

For example, in one example, the second insulating layer 13 may be formed of a thermosetting material or may be formed of a thermoplastic material.

In viewing one example referring to FIG. 3B, in the step of stacking the second insulating layer, the second insulating layer 13 where a metal layer 15 is attached to one side peripheral region thereof may be stacked on the upper and lower regions of the first insulating layer 11. For example, the metal layer 15 may be a copper layer, but it is not limited to this.

And also, referring to FIGS. 3B, 3C and 3D, in another example, the method for manufacturing the core substrate may further include a step of attaching the metal layer. At this time, in the step of attaching the metal layer, the metal layer 15 is attached to the peripheral region of the second insulating layer 13. For example, the metal layer 15 may be a copper layer.

At this time, the step of attaching the metal layer may be performed before, after or simultaneously. FIG. 3B represents a view to precede the step of attaching the metal layer before the step of stacking the second insulating layer, and FIG. 3D represents a view to precede the step of attaching the metal layer after the step of stacking the second insulating layer. Referring to FIG. 3C, the step of attaching the metal layer may be performed before, after or simultaneously the step of stacking the second insulating layer. For example, similar to FIG. 3B, in case when the step of attaching the metal layer is performed before the step of stacking the second insulating layer, the metal layer 15 is attached to one side peripheral region of the second insulating layer 13 and the second insulating layer 13 attached thereto the metal layer 15 may be stacked on the upper and lower regions of the first insulating layer 11. For example, referring to FIG. 3D, in case when the step of attaching the metal layer is performed after the step of stacking the second insulating layer, the metal layer 15 may be attached to the peripheral region of the second insulating layer 13 stacked on the upper and lower regions of the first insulating layer 11 by a method such as plating, sputtering or the like. And also, referring to FIG. 3C, the metal layer 15 can be attached on the second insulating layer 13 by the medium of an attaching resin or a primer resin 17. In case when the step of attaching the metal layer and the step of stacking the second insulating layer are performed at the same time, the second insulating layer 13 is placed on the upper and lower regions of the first insulating layer 11 and the metal layer 15, for example, a copper layer, is placed on the peripheral region of the second insulating layer 13 or, as shown in FIG. 3C, after the metal layer 15, e.g., the copper layer, on which the primer resin 17 is coated, is placed, the metal layer 15, e.g., the copper layer, can be attached on the second insulating layer 13 by performing a thermal compressing process.

Substrate with Built-in Electronic Components

And then, a method for manufacturing a core substrate in accordance with a third embodiment of the present invention will be specifically described with reference to the drawings. At this time, the core substrate in accordance with the above-described first embodiment and FIGS. 1 to 2B will be referred; and, accordingly, the overlapped explanations will be omitted.

FIGS. 4A and 4B are views schematically showing a substrate with built-in electronic components in accordance with another embodiment of the present invention.

Referring to FIG. 4A, a substrate with built-in electronic components in accordance with one example includes a core substrate 10 and an electronic component 20. And also, in one example, as shown in FIG. 4A, it can further include a circuit pattern layer 15′ formed on a second insulating layer 13 of the core substrate 10.

At first, referring FIG. 4A, the core substrate 10 includes the cavity 10a. The electronic component 20 is inserted into the cavity 10a. And also, the core substrate 10 includes the first insulating layer 11 and the second insulating layer 13 stacked on the upper and lower regions of the first insulating layer 11.

At this time, the glass transition temperature of the first insulating layer 11 is higher than that of the second insulating layer 13. By manufacturing the core substrate 10 by stacking the second insulating layer 13 on the upper and lower regions of the first insulating layer 11 of the semi-cured state with a high glass transition temperature, the first insulating layer 11 of the semi-cured state flows into a gap space between the cavity 10a and the built-in electronic components 20 during the manufacturing of the substrate with built-in electronic components, thereby filling the gap space. At this time, the filled material of the first insulating layer 11 by flowing into the gap space fixes the built-in electronic components 20 from the middle thereof.

In one example, the first insulating layer 11 can include a thermoplastic resin. Since the first insulating layer is the thermoplastic resin, the electronic component 20 is inserted into the cavity 10a formed in the core substrate 10 during the manufacturing of the substrate with built-in electronic components, if the second insulating layer 13 of the core substrate 10 is thermally compressed, the first insulating layer 11 as the thermoplastic resin is easily flown into the space between the cavity 10a and the electronic component 20 at a flow state, thereby fixing the electronic component 20.

At also, in one example, the first insulating layer may be a semi-cured insulating layer. Since the first insulating layer 11 is the semi-cured state, during incorporating the electronic component into the cavity 10a, if the second insulating layer 13 is compressed, the material of the first insulating layer as an intermediate layer flows into the space between the cavity 10a and the built-in electronic components 20 at the flow state, thereby fixing the electronic component 20.

Subsequently, in FIG. 4A, the second insulating layer 13 is stacked on the upper and lower regions of the first insulating layer 11. At this time, the second insulating layer 13 may be formed of a material a low glass transition temperature.

And also, referring to FIG. 4A, reviewing one example with reference to FIG. 4A, the circuit pattern layer 15′ formed on the upper and lower regions of the second insulating layer 13 of the core substrate can be further included. That is, the circuit pattern layer 15′ is formed on the upper region of the second insulating layer 13 formed on the upper region of the first insulating layer 11 and the lower region of the second insulating layer formed on the lower region of the first insulating layer, respectively. For example, the circuit pattern layer 15′ may a pattern layer obtained by fabricating the copper layer. And also the core substrate 10 can further include the circuit pattern layer 15′ formed on the peripheral region as well as a through hole 10b to connect the circuit pattern layer 15′ of the upper and lower regions of the core substrate 10.

Thereafter, the electronic component 20 will be reviewed with reference to FIG. 4A. The electronic component 20 is inserted into the cavity 10a of the core substrate 10. At this time, the electronic component 20 is fixed to the cavity 10a by the insulating material flown from the first insulating layer 11. For example, the electronic component 20 may be an active device such as an IC chip or may be a passive device such as an MLCC. In FIGS. 4A and 4B, although a capacitor model is shown as an example of the electronic component 20, it is not limited to this. Since the electronic component 20 is inserted into the cavity 10a of the core substrate 10, a width of the cavity 10a is greater than a size of the electronic component 20 conventionally. Accordingly, after the electronic component is inserted, a gap is generated between the cavity 10a and the electronic component 20, the gap is needed to be filled with the insulating material. In conventional, although a build-up insulating layer is stacked by inserting the electronic component of a single core layer and the gap between the cavity and the electronic component is filled with the insulating material at the up and down direction, there is a problem that a void is generated at the gap between the cavity and the electronic component. In the present invention, the first insulating layer 11 as the intermediate layer of the semi-cured state by thermally compressed the core substrate 10 having the cured second insulating layer 13 and the semi-cured first insulating layer 11, which are obtained by stacking and thermally compressing the second insulating layer 13 on the upper and the upper regions of the first insulating layer across the first insulating layer 11 of a high glass transition temperature in the middle without the single core layer, flows into the gap space between the cavity 10a and the electronic component 20 and fixes the electronic component 20, thereby solving the problem of void generations.

Thereafter, referring to FIG. 4B, reviewing a still another example. Referring to FIG. 4B, the substrate with built-in electronic components in accordance with another embodiment can further include a third insulating layer 30. At this time, the third insulating layer 30 covers the circuit pattern layer 15′ by being stacked on the second insulating layer 13. For example, the third insulating layer 30 may be formed of a material having a glass transition temperature lower than that of the first insulating layer 11.

For example, at this time, the gap is formed between the sidewall of the cavity 10a and the electronic component 20, the insulating material of the first insulating layer 11 as well as the insulating material of the third insulating layer permeates the gap to be filled. For example, after stacking the third insulating layer 30, the electronic component 20 can be fixed without voids by allowing the insulating material of the third insulating layer 30 to be smeared into an unfilled space among the space between the cavity 10a previously and partially filled with the insulating material of the first insulating layer 11 and the electronic component 20 to be supplementary filled.

For example, the metal layer 35 is formed on the upper and lower regions of the third insulating layer 30, e.g., the upper region of the third insulating layer 30 stacked on the upper region of the second insulating layer 13 and the lower region of the third insulating layer 30 stacked on the lower region of the second insulating layer 13. Although not shown, the metal layer 35 of FIG. 4b can form the circuit pattern layer by being fabricated.

And also, although not shown, for example, the third insulating layer 30 can further include a circuit pattern layer formed by fabricating the metal layer 35 on the third insulating layer 30, the circuit pattern 15′ on the core substrate 10 and/or a via to be connected with the electrodes of the electronic component 20.

Method for Manufacturing Substrate with Built-in Electronic Components

And then, a method for manufacturing a substrate with built-in electronic components in accordance with a fourth embodiment of the present invention will be specifically described with reference to the drawings. At this time, the substrate with built-in electronic components in accordance with the above-described third embodiment and FIGS. 3A to 3C and FIGS. 4A and 4B will be referred; and, accordingly, the overlapped explanations will be omitted.

FIGS. 5A to 5E are views schematically showing each step of a method for a substrate with built-in electronic components in accordance with still another embodiment of the present invention.

Referring to FIGS. 5A to 5C, the method for manufacturing the substrate with built-in electronic components in accordance with one example can include a step of preparing a core substrate (referring to FIG. 5A), a step of inserting an electronic component (referring to FIG. 5B) and a step of fixing the electronic component (referring to FIG. 5A). The method for manufacturing the substrate with built-in electronic components method will be reviewed in detail with reference to the drawings.

At first, referring to FIG. 5A, in the step of preparing the core substrate, the core substrate 10 including a cavity 10a, a first insulating layer 11 and a second insulating layer 13 is prepared. At this time, the first insulating layer 11 is made of a material having a glass transition temperature higher than that of the second insulating layer 13. Related to the step of preparing the core substrate, the items not explained herein below will be referred to the method for manufacturing the core substrate previously described above.

For example, in one example, in one example, the step of preparing the core substrate can include a step of stacking the second insulating layer and a step of compressing. In the step of stacking the second insulating layer, the second insulating 13 is stacked on the upper and the lower regions of the first insulating layer 11. And then, in the step of the compressing, the second insulating layer 13 and the first insulating layer 11 can be compressed at a temperature which is lower than the glass transition temperature of the first insulating layer 11 and higher than the glass transition temperature of the second insulating layer 11.

At this time, for example, the first insulating layer 11 may be a semi-cured insulating layer. At this time, the second insulating layer 13 stacked on the upper and lower regions of the first insulating layer 11 of the core substrate 10 may be an insulating layer of the cured state. For example, if the semi-cured second insulating layer is stacked and cured on the upper and lower regions of the first insulating layer 11 during the manufacturing of the core substrate 10, the core substrate 10 may be obtained together with the cured second insulating layer 13 and the semi-cured first insulating layer 11. For example, the core substrate 10 can be formed by stacking and curing the second insulating layer 13 on the upper and lower regions of the first insulating layer 11 by using a prepreg insulating layer. For example, in one example, the material of the second insulating layer 13 may be a thermosetting resin.

And also, as shown in FIG. 5A, in one example, the core substrate 10 can further include a metal layer 15 formed on the second insulating layer 13. At this time, the process for forming the metal layer 15 will be referred to the step of attaching the metal layer in the above-described method for manufacturing the core substrate.

Thereafter, referring to FIG. 5B, in the step of inserting the electronic component, the electronic component 20 is inserted into the cavity of the core substrate 10. At this time, although not shown, an adhesive tape is attached to one side of the core substrate 10 formed thereon the cavity 10a to temporarily fix the electronic component and the electronic component 20 can be mounted on the adhesive tape in the cavity 10a of the core substrate 10.

And then, referring to FIG. 5C, in the step of fixing the electronic component, the core substrate 10 inserted therein the electronic component 20 is thermally compressed. For example, although not shown, the electronic component 20 is inserted into the cavity 10a of the core substrate 10, wherein the adhesive tape is attached to one side of the core substrate 10a, and the core substrate 10 inserted therein the electronic component 20 is compressed up and down. At this time, a height of the electronic component 20 is greater than a thickness of the core substrate 10. According to the thermal compression of the core substrate 10, while the first insulating layer 11 to for the intermediate layer of the core substrate 10 is flown, it flows into the gap between the cavity 10a and the electronic component 20 and to fill the gap space. The material of the first insulating layer filled by flowing into the gap between the cavity 10a and the electronic component 20 due to the thermal compression of the core substrate 10 fixes the electronic component 20. For example, in the step of fixing the electronic component, for example, the temperature during the thermal compression may be higher than the glass transition temperature of the first insulating layer 11 or, if the first insulating layer 11 as the intermediate layer of the core substrate 10 is the semi-cured state, the electronic component 20 may be fixed by allowing the material of the first insulating layer 11 to flow into the gap between the cavity 10a and the electronic component 20 due to the thermal compression even below the glass transition temperature of the first insulating layer 11. And also, at this time, since the electronic component 20 is attached and fixed from the middle thereof by the material of the first insulating layer 11 filled by being flown from the gap between the cavity 10a and the electronic component 20, the generation of a void such as a prior art can be suppressed. After thermally compressing the core substrate 10, the adhesive tape attached to one side is removed.

Thereafter, reviewing still another example with reference to FIG. 5D. In the present example, in the step of preparing the core substrate, the prepared core substrate 10 includes the first insulating layer 11, the second insulating layer 13 and the metal layer 15 formed on the peripheral region of the second insulating layer 13. At this time, referring to FIG. 5D, after the step of fixing the electronic component (referring to FIG. 5C), the method for manufacturing the substrate with built-in electronic components can further include a step of forming a circuit pattern layer 15′. Referring to FIG. 5D, in the step of forming the circuit pattern layer 15′, the circuit pattern layer 15′ is formed by fabricating the metal layer 15 of the core substrate 10. The pattern formation method may use a well known method. For example, an SAP method, an MSAP method, a TENTING method or the like may be used, but it is not limited to this.

Thereafter, reviewing still another example with reference to FIG. 5E. Referring to FIG. 5E, the method for manufacturing the substrate with built-in electronic components can further include a step of stacking the third insulating layer. At this time, a metal layer 35 is attached to one side peripheral region of the third insulating layer 30. The third insulating layer 30 attached thereto the metal layer 35 is stacked on the upper and lower peripheral regions of the second insulating layer 13 and the circuit pattern layer 15′.

And also, although not shown, the method for manufacturing the substrate with built-in electronic components can further include a step of forming a second circuit pattern layer. Further, although not shown, simultaneously or before the step of forming the second circuit pattern layer, the method for manufacturing the substrate with built-in electronic components can further include a step of forming a via to be connected the second pattern layer to be formed by fabricating the metal layer 35, the first circuit pattern layer 15′ obtained by fabricating the metal layer 15 and/or an electrode of the electronic components.

In the exemplary embodiments, the core substrate 10 before inserting the electronic component 20 may have a thickness thicker than that of the electronic component 20. And also, after inserting the electronic component 20 and thermally compressing it, the thickness of the core substrate 10 may substantially be equal to that of the electronic component 20.

In one embodiment, in case when the electronic component 20 is an MLCC, an external electrode of the electronic component 20 and the circuit pattern layer 15′ have the substantially same top surface. In this case, since, in the substrate with built-in electronic components, the patterns of the metal materials or the positions of the layers are arranged on the same plane and have the symmetrical construction on the whole, it can have a structurally stability improved by preventing a warpage phenomenon.

According to the embodiments described above, it is possible to incorporate a layer having a high glass transition temperature into a core substrate, to fill a cavity gap with an insulating material flown from an insulating layer incorporated into the core substrate during the manufacturing a substrate with built-in electronic components and to fix the electronic component at the same time.

It is apparent that various effects which have not been directly mentioned according to the various embodiments of the present invention can be derived by those skilled in the art from various constructions according to the embodiments of the present invention.

The above-described embodiments and the accompanying drawings are provided as examples to help understanding of those skilled in the art, not limiting the scope of the present invention. Further, embodiments according to various combinations of the above-described components will be apparently implemented from the foregoing specific descriptions by those skilled in the art. Therefore, the various embodiments of the present invention may be embodied in different forms in a range without departing from the essential concept of the present invention, and the scope of the present invention should be interpreted from the invention defined in the claims. It is to be understood that the present invention includes various modifications, substitutions, and equivalents by those skilled in the art.

What is claimed is:

1. A core substrate comprising:
a first insulating layer; and
a second insulating layer stacked on upper and lower surfaces of the first insulating layer and made of a material with a glass transition temperature lower than that of the first insulating layer.

2. The core substrate according to claim 1, further comprising:
a metal layer stacked on upper and lower surfaces of the second insulating layer.

3. The core substrate according to claim 1, wherein the first insulating layer includes a thermoplastic resin.

4. The core substrate according to claim 1, wherein the first insulating layer is a semi-hardening insulating layer and the second insulating layer is a hardening insulating layer.

5. A substrate with built-in electronic components comprising:
a core substrate provided with a cavity and including a first insulating layer and a second insulating layer stacked on upper and lower surfaces of the first insulating layer, wherein the second insulating layer is made of a material with a glass transition temperature lower than that of the first insulating layer; and
an electronic component fixed by an insulating material flown from the first insulating layer by being inserted into the cavity.

6. The substrate with built-in electronic components according to claim 5, further comprising:
a circuit pattern layer formed on upper and lower surfaces of the second insulating layer.

7. The substrate with built-in electronic components according to claim 5, wherein the first insulating layer includes a thermoplastic resin.

8. The substrate with built-in electronic components according to claim 6, further comprising:
a third insulating layer for covering the circuit pattern layer by being stacked on the second insulating layer.

9. The substrate with built-in electronic components according to claim 8, wherein a gap is formed between a sidewall of the cavity and the electronic component and the gap is filled with the third insulating layer together with the first insulating layer.

10. A method for manufacturing a substrate with built-in electronic components, comprising:
preparing a core substrate provided with a cavity and including a first insulating layer and a second insulating layer stacked on upper and lower surfaces of the first insulating layer, wherein the second insulating layer is made of a material with a glass transition temperature lower than that of the first insulating layer;
inserting the electronic component into the cavity; and
fixing the electronic component by flowing an insulating material of the first insulating layer into a gap between the cavity and the electronic component by thermal compressing the core substrate inserted therein the electronic component.

11. The method for manufacturing a substrate with built-in electronic components according to claim 10, wherein the core substrate further comprises a metal layer formed on the second insulating layer, further comprising:
forming a circuit pattern by fabricating the metal layer.

12. The method for manufacturing a substrate with built-in electronic components according to claim 11, further comprising:
forming a third insulating layer to cover the second insulating layer and the circuit pattern.

13. The method for manufacturing a substrate with built-in electronic components according to claim 12, wherein the gap is filled with the third insulating layer together with the first insulating layer.

14. The method for manufacturing a substrate with built-in electronic components according to claim 10, wherein preparing the core substrate includes:
stacking the second insulating layer on the upper and the lower surfaces of the first insulating layer; and
compressing the second insulating layer and the first insulating layer under a temperature lower than the glass transition temperature of the first insulating layer and higher than the glass transition temperature of the second insulating layer.

15. The method for manufacturing a substrate with built-in electronic components according to claim 10, wherein thermal compressing the core substrate is performed at a temperature higher than the glass transition temperature of the first insulating layer.
